(19) United States
(12) Patent Application Publication
(10) Pub. No.: US 2026/0246366 A1
(43) Pub. Date: Aug. 20, 2026

(54) POWER CONVERSION DEVICE

(71) Applicant: MITSUBISHI ELECTRIC MOBILITY CORPORATION, Tokyo (JP)

(72) Inventors: Naoki KOIKE, Tokyo (JP); Hiroshi IKARASHI, Tokyo (JP); Kazutoshi AWANE, Tokyo (JP); Masayuki YAMANO, Tokyo (JP)

(73) Assignee: MITSUBISHI ELECTRIC MOBILITY CORPORATION, Tokyo (JP)

(21) Appl. No.: 19/161,425

(22) PCT Filed: Apr. 25, 2023
(86) PCT No.: PCT/JP2023/016204

§ 371 Date: Sep. 2, 2025

(51) Int. Cl. H02M 1/32; H02M 3/00; H05K 1/11; H05K 7/20

(52) U.S. Cl. CPC H02M 1/32; H02M 3/003; H05K 1/116; H05K 7/20927; H05K 7/20945; H05K 2201/10181

(57) ABSTRACT

A power conversion device such that a short-circuit or an insulating failure between fuse terminals after a fuse is fused due to an overcurrent or the like when an abnormality occurs can be prevented are obtained. A power conversion device includes a printed circuit board, a cooler disposed above the printed circuit board and having a coolant channel in an interior thereof and a shielding plate disposed between the printed circuit board and the cooler, wherein the printed circuit board includes a substrate having a through hole and a fuse that is disposed opposing the through hole and is attached to the substrate via a connection terminal, wherein the fuse is provided separated by an interval from the substrate in such a way that a space is formed.

### TECHNICAL FIELD

The present application relates to the field of a printed circuit board and a power conversion device.

### BACKGROUND ART

To date, with regard to a printed circuit board wherein a pattern fuse is provided together with a conductive pattern, a printed circuit board such that an insulating hole is provided in a direction following the pattern fuse in a position lateral to the pattern fuse has been proposed in order that no insulating failure occurs after fusing of the pattern fuse (for example, refer to Patent Literature 1).

When a pattern fuse fuses, copper foil or solder, which is one of constituent substances of the pattern fuse, vaporizes due to heat, or liquefies and disperses, but the dispersed constituent substances may adhere to the printed circuit board again. Further, when the constituent substances adhere between neighboring patterns, the neighboring patterns short-circuit, and an insulating failure occurs. Consequently, the conventional printed circuit board disclosed in Patent Literature 1 is such that an insulating hole is provided in a direction following the pattern fuse in a position lateral to the pattern fuse in order to prevent an insulating failure between neighboring patterns.

### CITATION LIST

### Patent Literature

PTL 1: JPH07-30213A

### SUMMARY OF INVENTION

### Technical Problem

However, there is a problem with the conventional printed circuit board disclosed in Patent Literature 1 in that even though an insulating failure between neighboring patterns can be prevented, a short-circuit or an insulating failure between fuse terminals after fusing of a fuse cannot be prevented. Because of this, there is a problem in that when fuse terminals are short-circuited by a conductive foreign body or the like after a pattern fuse is fused due to a large current caused by a circuit abnormality or the like, the large current continues to flow. Also, there is a problem in that when a printed circuit board is mounted in, for example, a power conversion device, a short-circuit or an insulating failure between fuse terminals caused by a foreign body generated from a part mounted in the power conversion device cannot be prevented in the same way.

The present application has been made to disclose a technology for solving the above problem, and an object of the present application is to provide a printed circuit board and a power conversion device such that a short-circuit or an insulating failure between fuse terminals after a fuse is fused due to an overcurrent or the like when an abnormality occurs can be prevented.

### Solution to Problem

A printed circuit board disclosed in the present application includes a substrate having a through hole and a fuse that is disposed opposing the through hole and is attached to the substrate via a connection terminal, wherein the fuse is provided separated by an interval from the substrate in such a way that a space is formed.

Also, a power conversion device disclosed in the present application includes the printed circuit board, a cooler disposed above the printed circuit board and having a coolant channel in an interior thereof, and a shielding plate disposed between the printed circuit board and the cooler.

### Advantageous Effects of Invention

According to a printed circuit board and a power conversion device disclosed in the present application, a short-circuit or an insulating failure between fuse terminals after a fuse is fused due to an overcurrent or the like when an abnormality occurs can be prevented.

### BRIEF DESCRIPTION OF DRAWINGS

FIG. 1 is an enlarged perspective view showing a printed circuit board according to a first embodiment.

FIG. 2 is an enlarged perspective view showing a printed circuit board according to a second embodiment.

FIG. 3 is an enlarged perspective view showing a printed circuit board according to a third embodiment.

FIG. 4 is an enlarged perspective view showing a printed circuit board according to a fourth embodiment.

FIG. 5 is a schematic view showing a power conversion device according to a fifth embodiment.

### DESCRIPTION OF EMBODIMENTS

Hereafter, a printed circuit board according to a first embodiment will be described, based on the drawings. In the drawings, identical reference signs indicate identical or corresponding components.

### First Embodiment

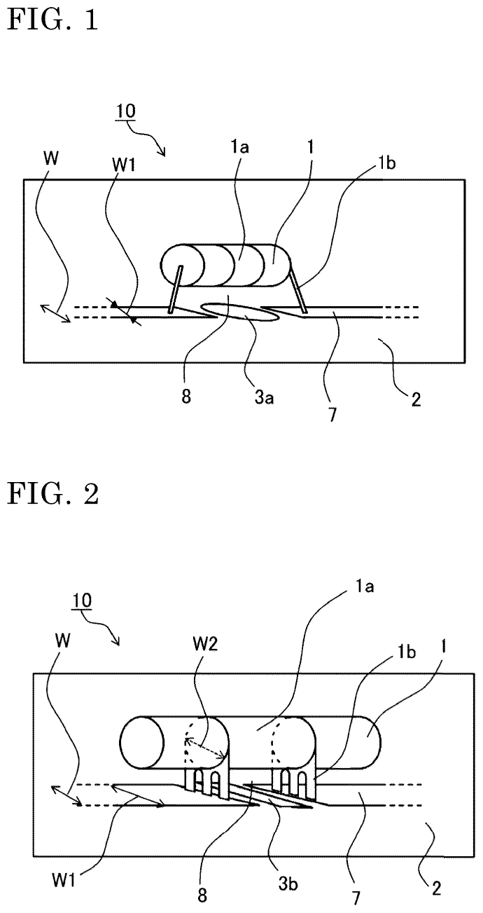

FIG. 1 is an enlarged perspective view showing a printed circuit board according to a first embodiment. As shown in FIG. 1, a printed circuit board 10 of the first embodiment includes a substrate 2, which has a through hole 3a, and a fuse 1 that is disposed opposing the through hole 3a and is attached to the substrate 2 via a connection terminal 1b, and the fuse 1 is provided with an interval between the fuse 1 and the substrate 2.

A wiring pattern 7 is provided on the substrate 2, and the connection terminal 1b of the fuse 1 is connected to the wiring pattern 7 of the printed circuit board 10. Also, the connection terminal 1b is formed of, for example, copper with tin plating, and the wiring pattern 7 is formed of, for example, copper. Further, in order that a main body portion la of the fuse 1 does not come into contact with the substrate 2, the connection terminal 1b is formed to have a predetermined length. Further, the printed circuit board 10 has a space 8 between the main body portion la of the fuse 1 and the substrate 2.

The fuse 1 mounted on the printed circuit board 10 according to the first embodiment is, for example, a glass tube fuse. The printed circuit board 10 to which the fuse 1 is attached is incorporated in a power conversion device 50 having, for example, a cooler 5, as will be described hereafter. For example, there is a possibility of a coolant of the cooler 5, or a conductive foreign body such as a solder ball, flowing as far as a position of the fuse 1 on the printed circuit board 10 due to a problem with the cooler 5 or an impact of an accident or the like. For example, when the main body portion la of the fuse 1 and the substrate 2 of the printed circuit board 10 come into contact, there is a possibility of the main body portion la of the fuse 1 being wettened by the coolant, or of a conductive foreign body such as a solder ball remaining between the main body portion la of the fuse 1 and the substrate 2.

However, the fuse 1 mounted on the printed circuit board 10 according to the first embodiment is such that there is the sufficient space 8 between the main body portion 1a of the fuse 1 and the substrate 2 of the printed circuit board 10, because of which a short-circuit or an insulating failure between the connection terminals 1b of the fuse 1 caused by the coolant of the cooler 5 or a conductive foreign body such as a solder ball can be prevented.

Also, the printed circuit board 10 of the first embodiment is such that the through hole 3a is provided between the connection terminals 1b of the fuse 1. The through hole 3a needs to be of a sufficient size in order to secure an insulating distance between the connection terminals 1b. Specifically, a length of a width direction W of the through hole 3a is preferably an aperture width longer than, for example, a width W1 of the wiring pattern 7. Also, the through hole 3a is a hole portion (a hole) that has no bottom face, and is formed in such a way that a necessary insulating distance or more is secured when a line is drawn between a position of one wiring pattern 7 and positions of each of other wiring patterns 7.

Configuring in this way means that even when coolant or a conductive foreign body such as a solder ball flows between the connection terminals 1b of the fuse 1, the foreign body is removed by the through hole 3a, and an insulating distance between the connection terminals 1b of the fuse 1 can be secured.

Also, an insulating distance between the connection terminals 1b of the fuse 1 can be secured by the through hole 3a being of a circular form, including a perfect circle, an ellipse, and the like, of a sufficient size, as shown in FIG. 1. Furthermore, by using a tool that also opens a hole through which a screw or the like for attaching the substrate 2 of the printed circuit board 10 passes, a dedicated tool for forming the through hole 3a is unneeded, and a reduction in the number of processes when producing the printed circuit board 10 can be achieved.

As heretofore described, the printed circuit board 10 according to the first embodiment includes the substrate 2, which has the through hole 3a, and the fuse 1, which is disposed opposing the through hole 3a and is attached to the substrate 2 via the connection terminal 1b, and the fuse 1 is separated by an interval from the substrate 2, and is provided in such a way that the space 8 is formed between the fuse 1 and the substrate 2. Consequently, a short-circuit or an insulating failure between the connection terminals 1b of the fuse 1 after a fuse is fused due to an overcurrent or the like when an abnormality occurs can be prevented.

### Second Embodiment

FIG. 2 is an enlarged perspective view showing a printed circuit board according to a second embodiment. In FIG. 2, a reference sign identical to a reference sign used in order to describe the printed circuit board 10 in the first embodiment being allotted indicates an identical or corresponding configuration, and a description thereof is omitted.

Configurations of the printed circuit board 10 according to the second embodiment differing from that of the first embodiment are that a width of the connection terminal 1b of the fuse 1 is greater in the width direction W, and that a form of a through hole 3b is polygonal, including a rectangle and the like. The printed circuit board 10 according to the second embodiment is such that the connection terminal 1b has, for example, a width approximately identical to a width W2 of the fuse 1. Also, in order that the main body portion la of the fuse 1 does not come into contact with the substrate 2, the connection terminal 1b has a predetermined height.

In particular, a length between the connection terminals 1b or between the wiring patterns 7 being comparatively short with respect to the connection terminal 1b of the fuse 1 being long in the width direction W means that when end portions in identical positions of the opposing connection terminals 1b are joined by a straight line when the form of the through hole is a perfect circle, the straight line may not touch the through hole. Meanwhile, even when the form of the through hole is elliptical, an aperture of the through hole at an end portion of the connection terminal 1b is small in comparison with that at a central portion, meaning that a sufficient insulating distance can conceivably not be secured.

In response to this, according to the printed circuit board 10 according to the second embodiment, the form of the through hole 3b is rectangular, as shown in FIG. 2, whereby the width of the through hole 3b is the same seen from any position of the connection terminal 1b, meaning that a sufficient insulating distance can be secured between the connection terminals 1b of the fuse 1.

In FIG. 2, a width of the rectangular through hole 3b is, for example, approximately the same as the width W1 of the wiring pattern 7 of the substrate 2, but as there is no problem provided that a sufficient insulating distance is secured between the connection terminals 1b of the fuse 1, the width of the rectangular through hole 3b need not necessarily be the same as the width W1 of the wiring pattern 7 of the substrate 2. Also, a multiple of cavities formed in the connection terminal 1b shown in FIG. 2 are not essential.

### Third Embodiment

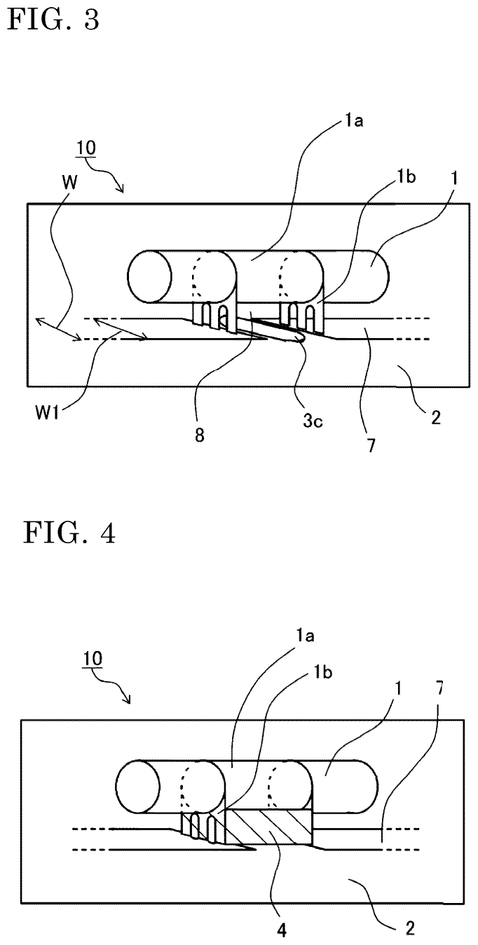

FIG. 3 is an enlarged perspective view showing a printed circuit board according to a third embodiment. In FIG. 3, a reference sign identical to a reference sign used in order to describe the printed circuit board 10 in the first embodiment and the second embodiment being allotted indicates an identical or corresponding configuration, and a description thereof is omitted.

The printed circuit board 10 according to the third embodiment differs from the printed circuit board 10 according to the second embodiment in that a through hole 3c is formed by a multiple of holes being connected.

As shown in FIG. 3, the printed circuit board 10 according to the third embodiment is such that the through hole 3c is formed by a multiple of holes being connected continuously in the width direction W of the connection terminal 1b of the fuse 1.

According to the printed circuit board 10 according to the third embodiment, the through hole 3c formed by a multiple of holes being connected enables an insulating distance to be secured between the connection terminals 1b of the fuse 1. Also, owing to the through hole 3c being formed in this way, there is no need to prepare a dedicated tool in accordance with a kind of form, size, or the like of the through hole 3c, and the number of processes when producing the printed circuit board 10 is reduced.

Also, by using a tool that also opens a hole through which a screw or the like for attaching the printed circuit board 10 passes at this time, a dedicated tool or change in set-up is unneeded in the same way, and the number of processes when producing the substrate 2 of the printed circuit board 10 is further reduced.

### Fourth Embodiment

FIG. 4 is an enlarged perspective view showing a printed circuit board according to a fourth embodiment. In FIG. 4, a reference sign identical to a reference sign used in order to describe the printed circuit board in the first embodiment to the third embodiment being allotted indicates an identical or corresponding configuration, and a description thereof is omitted.

As shown in FIG. 4, the printed circuit board 10 according to the fourth embodiment is such that the connection terminal 1b of the fuse 1 is connected to the wiring pattern 7 of the substrate 2. Also, in order that the main body portion la of the fuse 1 does not come into contact with the substrate 2, the connection terminal 1b has a predetermined height. Also, the printed circuit board 10 has the space 8 between the main body portion la of the fuse 1 and the substrate 2.

Furthermore, the printed circuit board 10 according to the fourth embodiment is such that the space 8 is filled with a protective member 4 of resin or the like. Owing to the space 8 being filled with the protective member 4, a coolant or a conductive foreign body such as a solder ball is unable to enter between the connection terminals 1b of the fuse 1, an insulating distance between the connection terminals 1b of the fuse 1 can be secured, and a short-circuit or an insulating failure between fuse terminals can be prevented.

Also, the printed circuit board 10 of the fourth embodiment is such that an advantage in that earthquake resistance of the fuse 1 improves can also be expected.

The printed circuit board 10 shown in FIG. 4 is shown in a state wherein a whole of the space 8 between the connection terminals 1b of the fuse 1 is filled with the protective member 4, but the same advantage is obtained when only at least the connection terminal 1b at either end is covered with the protective member 4.

### Fifth Embodiment

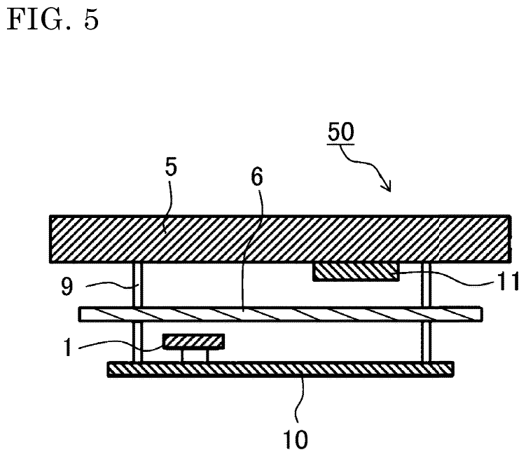

FIG. 5 is a schematic view showing a power conversion device according to a fifth embodiment. As shown in FIG. 5, the power conversion device 50 according to the fifth embodiment includes the printed circuit board 10 according to the first embodiment to the fourth embodiment, the cooler 5, which is disposed above the printed circuit board 10 and has a coolant channel in an interior thereof, and a shielding plate 6 disposed between the printed circuit board 10 and the cooler 5. Also, the cooler 5 has a power semiconductor element 11, and a terminal of the power semiconductor element 11 is physically and electrically connected to the printed circuit board 10 by being soldered via a hole (not shown) formed on the shielding plate 6. The power semiconductor element 11 is connected to electronic parts (not shown) via the wiring pattern 7 of the printed circuit board 10. A support 9 for attaching the printed circuit board 10 and the shielding plate 6 is provided on the cooler 5.

As the power semiconductor element 11 of the power conversion device 50 generates considerable heat, the power conversion device 50, as shown in FIG. 5, is of a structure including the cooler 5, which has a coolant channel in the interior thereof, thereby cooling the power semiconductor element 11. When there is a problem such as porosity in the cooler 5, or damage or the like occurring due to an impact of a traffic accident or the like, there is a possibility of coolant leaking from the cooler 5.

According to the power conversion device 50 according to the fifth embodiment, the shielding plate 6 is provided between the cooler 5 and the printed circuit board 10, whereby an amount of coolant coming into contact with the printed circuit board 10 can be reduced, and an amount of coolant flowing between the connection terminals 1b of the fuse 1 can be reduced.

Provided that a length in a width direction of the shielding plate 6 is greater than a length in a width direction of the printed circuit board 10, and the printed circuit board 10 can be covered by the shielding plate 6, as shown in FIG. 5, coolant leaking out from the cooler 5 falls from an edge of the shielding plate 6 on an outer side of the printed circuit board 10 after coming into contact with the shielding plate 6, whereby the amount of coolant flowing onto the printed circuit board 10 can be greatly reduced.

Also, when an edge on an outer side of the shielding plate 6 is, for example, processed to face downward in a diagonally outward direction, coolant is diverted to a rear side (lower side) of the shielding plate 6 from the edge, and cases of coolant falling onto the printed circuit board 10 decrease. Also, when adopting a state in which the power semiconductor element 11 and the printed circuit board 10 are electrically connected by providing a hole in the shielding plate 6, a possibility of coolant on the shielding plate 6 falling onto the printed circuit board 10 from the hole can be reduced by processing a peripheral edge of the hole of the shielding plate 6 to, for example, face diagonally upward.

In this way, by processing the edge of the shielding plate 6 in such a way that the edge in a portion from which coolant falling onto the printed circuit board 10 causes a problem faces upward, and the edge in a portion on the outer side or the like of the printed circuit board 10, from which coolant falling causes no problem, faces downward, processing can be carried out appropriately without coolant falling onto the printed circuit board 10.

Also, when no coolant comes into contact with the printed circuit board 10, there is no longer any short-circuiting of a circuit caused by coolant, meaning that there is also no longer any fusing of the fuse 1. Also, by adopting a metal plate as the shielding plate 6, an advantage in that radiated noise is blocked can also be expected.

Although the present application is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments.

It is therefore understood that numerous modifications which have not been exemplified can be devised without departing from the scope of the present application. For example, at least one of the constituent components may be modified, added, or eliminated. At least one of the constituent components mentioned in at least one of the preferred embodiments may be selected and combined with the constituent components mentioned in another preferred embodiment.

### REFERENCE SIGNS LIST

1: fuse
1a: main body portion
1b: connection terminal
2: substrate
3a, 3b, 3c: through hole
4: protective member
5: cooler
6: shielding plate
7: wiring pattern
8: space
9: support
10: printed circuit board
11: power semiconductor element
50: power conversion device
W: width direction
W1, W2: width

1. A power conversion device, comprising:
a printed circuit board;
a cooler disposed above the printed circuit board and having a coolant channel in an interior thereof; and
a shielding plate disposed between the printed circuit board and the cooler, wherein the printed circuit board includes
a substrate having a through hole; and
a fuse that is disposed opposing the through hole and is attached to the substrate via a connection terminal, wherein
the fuse is provided separated by an interval from the substrate in such a way that a space is formed.

2. The power conversion device according to claim 1, characterized in that the through hole is circular or polygonal.

3. The power conversion device according to claim 1, characterized in that the through hole has an aperture width greater than a width of a wiring pattern on the substrate.

4. The power conversion device according to claim 1, characterized in that the through hole is formed by a multiple of holes being connected.

5. The power conversion device according to claim 1, characterized in that the through hole is formed using a tool used for a screw hole for attaching the substrate.

6. The power conversion device according to claim 1, characterized in that the connection terminal of the fuse is covered by a protective member.

7. The power conversion device according to claim 1, characterized in that the space between the fuse and the substrate is filled with a protective member.

8. (canceled)

9. The power conversion device according to claim 1, characterized in that a length in a width direction of the shielding plate is greater than a length in a width direction of the printed circuit board.

10. The power conversion device according to claim 1, characterized in that the cooler has a power semiconductor element, and
a terminal of the power semiconductor element is connected to the printed circuit board via a hole formed in the shielding plate.
